(19) United States
(12) Patent Application Publication
(10) Pub. No.: US 2026/0046995 A1
(43) Pub. Date: Feb. 12, 2026

(54) EUV LIGHT SOURCE HAVING A COMBINATION DEVICE

(71) Applicant: TRUMPF Lasersystems for Semiconductor Manufacturing SE, Ditzingen (DE)

(72) Inventors: Boris Regaard, Stuttgart (DE); Martin Lambert, Korb (DE); Oliver Schlosser, Filderstadt (DE); Tolga Ergin, Bietigheim- Bissingen (DE)

(21) Appl. No.: 19/366,563

(22) Filed: Oct. 23, 2025

Related U.S. Application Data
(63) Continuation of application No. PCT/EP2024/061254, filed on Apr. 24, 2024.

(30) Foreign Application Priority Data
Apr. 25, 2023 (DE) 10 2023 110 591.4

(51) Int. Cl. H05G 2/00; G03F 7/00

(52) U.S. Cl. CPC H05G 2/0086; G03F 7/70025; G03F 7/70033; G03F 7/70041; G03F 7/7005; H05G 2/0084

(57) ABSTRACT

An extreme ultraviolet (EUV) light source, including a first laser source for emitting a first laser beam, a second laser source for emitting a second laser beam, a combiner configured to combine the first laser beam and the second laser beam, and a beam-guide configured to jointly guide the first laser beam and the second laser beam into a target region for generating EUV radiation. The combiner is configured to supply the first laser beam and the second laser beam to the beam-guide for joint beam guidance via common optical units in a spatially separated manner and with a lateral offset.

### CROSS REFERENCE TO RELATED APPLICATIONS

This application is a continuation of International Application No. PCT/EP2024/061254 (WO 2024/223665 A1), filed on Apr. 24, 2024, and claims benefit to German Patent Application No. DE 10 2023 110 591.4, filed on Apr. 25, 2023. The aforementioned applications are hereby incorporated by reference herein.

### FIELD

The invention relates to an extreme ultraviolet (EUV) light source.

### BACKGROUND

An EUV light source is a radiation source which serves to emit EUV radiation. EUV radiation is understood to mean electromagnetic radiation having a wavelength of between 5 nm and 30 nm. EUV radiation finds application in particular in the semiconductor industry. Compared with lithography apparatuses that are currently widely used and are operated with wavelengths in the UV wavelength range, the use of EUV radiation for microlithographic manufacture allows the reliable production of components with significantly smaller structure sizes and thus results in a corresponding increase in performance.

The EUV light source mentioned above is suitable for the generation of EUV radiation by means of an LPP (laser-produced plasma) process. In such an EUV light source, a target material, which is typically a metal, in particular tin, is provided usually in droplet form in the target region by means of a provision device. In each case, a droplet is firstly irradiated with one, two or optionally more than two prepulses. The prepulse or the prepulses of a prepulse laser source serve(s) to prepare the droplet for irradiation by the main pulse, in particular to heat up the droplet, to expand it, to vaporize it and/or to produce a plasma. The subsequent irradiation of a droplet with a main pulse of a main pulse laser beam serves to transfer the target material into the plasma state. When the components of the plasma recombine, EUV radiation is emitted.

To generate the EUV radiation, it is necessary to guide at least one prepulse, usually at least two prepulses, and the main pulse to approximately the same focus position in the target region. It is advantageous if the impingement angle of the prepulse and the main pulse or the impingement angle of two or more prepulses in the target region deviate from each other as little as possible. In principle, the two or more laser beams can be guided into the target region via different optical units and focused in the target region via different focusing optical units. However, the space required for these optical units is considerable and makes a constructive solution with small relative impingement angles of the two laser beams complex.

U.S. Pat. No. 10,932,350 B2 proposes combining a prepulse laser beam and a main pulse laser beam or two prepulse laser beams in a beam combiner in order to focus both via a common focusing optical unit in a plasma generation region or on the target material. The beam combiner can be designed to be wavelength-selective and, for example, reflect the prepulse laser beam and transmit the main pulse laser beam.

EUV beam generating devices having two beam sources for emitting two laser beams, which are designed to combine or superpose the two laser beams, are described in addition to U.S. Pat. No. 10,932,350 B2, for example, also in WO 2015/036024 A1 and WO 2015/036025 A1.

WO 2015/036025 A1 describes an EUV radiation generation apparatus with a beam-guiding device which has a superposition device that superposes two laser beams entering a vacuum chamber through two different openings for joint beam guidance in the direction of the target region. In WO 2015/036025 A1, superposition is understood to mean that the two laser beams have a common beam axis after superposition and propagate coaxially along the common beam axis. The superposition device can, for example, be designed as a reflective optical element which is arranged in the vacuum chamber and which has a first surface region for reflecting the first laser beam and a second surface region, surrounding the first surface region in an annular manner, for reflecting the second laser beam.

### SUMMARY

In an embodiment, the present disclosure provides an extreme ultraviolet (EUV) light source, comprising a first laser source for emitting a first laser beam, a second laser source for emitting a second laser beam, a combiner configured to combine the first laser beam and the second laser beam, and a beam-guide configured to jointly guide the first laser beam and the second laser beam into a target region for generating EUV radiation. The combiner is configured to supply the first laser beam and the second laser beam to the beam-guide for joint beam guidance via common optical units in a spatially separated manner and with a lateral offset.

### BRIEF DESCRIPTION OF THE DRAWINGS

Subject matter of the present disclosure will be described in even greater detail below based on the exemplary FIGURES. All features described and/or illustrated herein can be used alone or combined in different combinations. The features and advantages of various embodiments will become apparent by reading the following detailed description with reference to the attached drawings, which illustrate the following:

FIG. 1 illustrates a schematic representation of an EUV light source with a combination device according to the present disclosure.

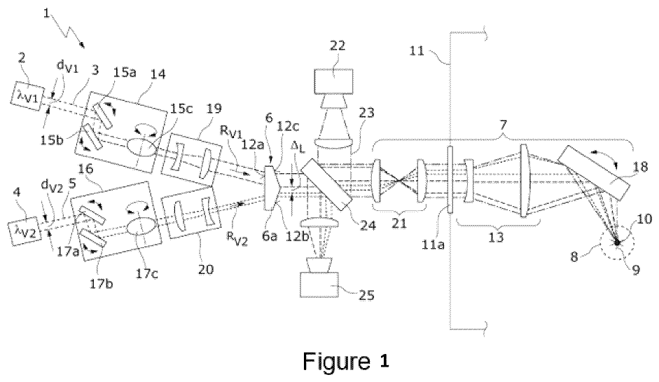

### DETAILED DESCRIPTION

In an embodiment, the present disclosure provides an EUV light source which makes it possible to guide two (or more) laser beams into a target region with low requirement for installation space and optical components and in particular to simplify the adjustment of the laser beams with respect to one another.

The foregoing advantages are achieved by an EUV light source of the type mentioned above in which the combination device is designed to supply the first laser beam and the second laser beam for joint beam guidance to the beam-guiding device via common optical units in a spatially separated manner and with a lateral offset. The combination device can also be designed to additionally supply a third, fourth, etc. laser beam for joint beam guidance to the beam-guiding device in a spatially separated manner and with a lateral offset.

For various reasons, it has proven advantageous if the first laser beam and the second laser beam are not spatially superposed in the combination device for joint beam guidance, i.e. if they do not have a common beam axis after combining, as is usually the case with superposition by polarization (e.g., by means of a polarization coupler), wavelength superposition (e.g., by means of a grating), temporal superposition (e.g., by means of an acousto-optical modulator) or with the coaxial superposition described in WO 2015/036025 A1. Joint beam guidance using such a spatial superposition with a common beam axis would result in thermally induced deformations or thermally induced changes in the optical density, which usually lead to a deterioration in the image quality, affecting all laser beams.

With superposition by polarization there is the additional problem that the superposition leads to losses at the polarization combiner. Furthermore, with polarization superposition, polarization can no longer be used to isolate the laser sources from backward-directed radiation. Backward radiation of the first laser beam also leads to potential interference with the second laser beam, and vice versa. When combining by wavelength superposition, laser beams of different wavelengths are necessary, but the availability of corresponding laser sources with the required pulse shapes and power densities may not be present. Furthermore, optical units that are sufficiently good at transmitting and reflecting both CO₂ laser radiation (˜10.6 μm wavelength), which is typically used for the main pulse laser beam (see below), and solid-state laser radiation (˜1 μm wavelength), which is typically used for the prepulse laser beam, are difficult to produce and therefore always lead to increased absorption in the optical elements and thus also to a deterioration in imaging quality. At the widely separated wavelengths specified above, the prepulse laser beam and the main pulse laser beam are typically guided via separate optical units, since this enables largely aberration-free imaging of the prepulse while maintaining a high average power of the main pulse.

In the EUV light source according to the present disclosure, a spatial superposition with a lateral offset takes place in the combination device, i.e. the laser beams emerge from the combination device spatially separated and with a lateral offset. The two laser beams pass through the optical units or the optical elements of the beam-guiding device (e.g., deflection and focusing optical unit) together, but along different, laterally offset beam paths. Within the beam-guiding device in the near field, the laser beams are typically collimated and substantially parallel (with a lateral offset). In the far field (after focusing by means of a focusing optical unit), the laser beams are focused in the target region at approximately the same focus position. The joint beam guidance in the beam-guiding device reduces the space required to guide the laser beams into the target region. In addition, by slightly tilting the first laser beam and the second laser beam relative to each other in the near field, their relative position in the far field (after focusing) can be adjusted or set (see below).

In an embodiment, the first laser source is a prepulse laser source for emitting a prepulse laser beam and the second laser source is a main pulse laser source for emitting a main pulse laser beam or a further prepulse laser source for emitting a further prepulse laser beam. The combination device can be used to combine a prepulse laser beam and the main pulse laser beam. Alternatively, it is provided for the combination device to combine a prepulse laser beam and an additional prepulse laser beam to one another. It is clear that the combination device can also be designed to supply the beam-guiding device with more than two prepulse laser beams or at least two prepulse laser beams and the main pulse laser beam for joint beam guidance in a spatially separated manner and with a lateral offset.

The wavelength of the or a prepulse laser beam and thus of the prepulses is referred to as the prepulse wavelength, and the wavelength of the main pulse laser beam and thus of the main pulses is referred to as the main pulse wavelength. The main pulse laser source is, for example, a CO₂ laser with a main pulse wavelength of approximately 10.6 μm, and the prepulse laser source is, for example, a solid-state laser, which can have a prepulse wavelength of approximately 1 μm. The use of a prepulse laser source in the form of a solid-state laser, compared to the use of a prepulse laser source in the form of an additional CO₂ laser, has the advantage of higher conversion efficiency and largely aberration-free focusing of the laser beam on the droplet. The reason for this, inter alia, is that short pulse durations and a sharp focusing of the prepulses on the target material are thus achieved, and that the prepulses have a different absorption behavior than the main pulses. It is also provided for the main pulse laser source to be a solid-state laser and for the main pulse laser beam to have a main pulse wavelength of approximately 1 μm, 2 μm or 5 μm in magnitude. If a plurality of prepulse laser sources are used, they can each have the same prepulse wavelength or (usually slightly) different prepulse laser wavelengths, which can be, for example, 1030 nm (Yb:YAG laser) and 1064 nm (Nd:YAG laser).

In an embodiment, a first wavelength of the first laser beam and a second wavelength of the second laser beam deviate from each other by not more than 70 nm, preferably by no more than 50 nm, and/or the first wavelength of the first laser beam and the second wavelength of the second laser beam are in a wavelength range between 350 nm and 5 μm, preferably between 500 nm and 2.5 μm.

As described above, optical units that transmit or reflect two wavelengths usually have increased absorption. If the wavelengths of the two laser beams are comparatively close to each other, this effect usually plays a minor role. This is particularly the case with the prepulse wavelengths of 1030 nm and 1064 nm specified above. In principle, the deviation between the two wavelengths can also be greater than specified above, although in this case the two laser beams can be guided via common optical units of the beam-guiding device. In the case of transmissive optical units, this usually requires that the two wavelengths are so close to each other that the same substrates and coatings, in particular in the form of anti-reflection coatings (see below), can be used. For example, when using a suitable substrate material, e.g., quartz glass, laser beams can also be guided via common transmissive optical units which have wavelengths that differ significantly more than specified above. If the main pulse wavelength is of a similar magnitude to the prepulse wavelength(s), the (at least one) prepulse laser beam and the main pulse laser beam can also be guided towards the target region via common optical units.

In an embodiment, the beam-guiding device comprises at least one transmissive optical unit having an anti-reflection coating, which is designed to suppress reflections of the first laser beam at the first wavelength and to suppress reflections of the second laser beam at the second wavelength, and/or the transmissive optical unit is formed from quartz glass. In the case of transmissive optical units, e.g., in the form of lenses, reflections when entering or exiting the substrate material usually lead to a reduction in transmission, which is why anti-reflection coatings are applied to such optical units. Anti-reflection coatings are typically optimized to suppress reflections at a wavelength corresponding to the wavelength of the impinging laser radiation. If the wavelengths of the two laser beams differ significantly from each other, it can be useful to apply an anti-reflection coating to the surface of a transmissive optical unit, which coating is optimized to suppress reflections at the two wavelengths of the two laser beams. For example, in this case the first wavelength can be approximately 515 nm and the second wavelength approximately 1 μm, or the first wavelength can be approximately 1 μm and the second wavelength approximately 2 μm.

The use of quartz glass as a material for transmissive optical units of the beam-guiding device, e.g., in the form of lenses, is advantageous because this material has comparatively high transmission in a wide wavelength range from approximately 350 nm to approximately 2.5 μm.

It is clear that the beam-guiding device can comprise not only transmissive optical units but also reflective optical units, e.g., in the form of mirrors. For example, a focusing optical unit of the beam-guiding device can be realized entirely or partially in the form of a reflective optical unit. The reflective optical units can be provided with a coating that is optimized for the reflection of both wavelengths.

In an embodiment, the first laser beam impinges on the combination device with a first beam direction and the second laser beam impinges on the combination device with a second beam direction different from the first beam direction. The different beam directions make it easier to guide the laser beams along spatially separated beam paths to the combination device. In this case, the combination device is typically designed to change the first and/or the second beam direction in order to orient the laser beams substantially parallel to one another. The beam direction can be changed in the combination device, for example, by refraction at (at least) one transmissive optical element or by beam deflection, for example, at (at least) one reflective optical element, in particular at a deflecting mirror. In the event that an odd number of beams enter the combination device, the beam in the middle can, for example, pass through the combination device without its beam direction being changed by the combination device.

In an embodiment, the combination device is designed to orient the first laser beam and the second laser beam parallel to one another. For the purposes of the present disclosure, parallel orientation means that the beam directions of the laser beams deviate from each other by less than 0.2° when exiting the combination device. As described above, by slightly tilting the beam directions of the laser beams in front of the combination device, their position in the far field can be adjusted, which leads to a slight deviation from the parallel orientation of the laser beams after the combination device. However, the tilt should not be chosen to be too large, since otherwise the laser beams can no longer be guided together via the optical elements of the beam-guiding device.

In an embodiment, the combination device comprises at least one prism. In particular, the combination device can consist of a prism. Since the refractive index of the prism material is wavelength-dependent, it is advantageous or necessary for the combination of two or more laser beams using a prism that they have the same or similar wavelengths. In the case that exactly two laser beams are combined, the prism can, for example, have a (flat) prism surface which serves as the beam entrance surface and onto which the laser beams impinge in a spatially offset manner. In this case, the angles of incidence of the two laser beams on the prism surface can, for example, have the same magnitude but a different sign. The two laser beams exit at two further prism surfaces which are each oriented at a wedge angle to the prism surface that serves as the beam entrance surface. By appropriately selecting the beam directions, the wedge angle and the refractive index of the prism material, the two laser beams can be oriented parallel or at a desired angle to each other when passing through the prism. The prism can be a symmetrical prism having a substantially triangular base, in which the wedge angles of the two prism surfaces serving as beam exit surfaces are equal in magnitude in relation to the beam entrance surface, but this is not necessarily the case. It can be advantageous if the beam paths of the laser beams cross before they impinge on the combination device, since this reduces the aperture on the subsequent optical units. Depending on the optical unit configuration, it can also be advantageous if the laser beams do not cross before they impinge on the combination device.

In an embodiment, the EUV light source comprises a first beam direction adjusting device for adjusting the first beam direction of the first laser beam and/or a second beam direction adjusting device for adjusting the second beam direction of the second laser beam. It is clear that, when three or more laser beams are combined, there can be three or more beam direction adjusting devices. As described above, it can be advantageous to adjust the beam directions of the laser beams, since by slightly tilting the beam directions relative to each other in the near field, the focus positions of the focused laser beams relative to each other in the target region can be set or adjusted. For adjusting the beam direction, the beam direction adjusting device can have adjustable deflection devices, for example in the form of deflecting mirrors or the like, which are designed to be movable, for example tiltable.

In an embodiment, the EUV light source comprises a first expansion device for changing, in particular for adjusting, a beam diameter of the first laser beam and/or a second expansion device for changing, in particular for adjusting, a beam diameter of the second laser beam. By specifying different beam diameters of the first (collimated) laser beam and the (collimated) second laser beam, different beam diameters can be generated for the beams at the focus position in the target region, although the joint focusing via the optical element(s) of the focusing device naturally requires an identical focal length. For example, by making the beam diameter of the laser beam a factor of 2 smaller, a focused beam diameter that is a factor of 2 larger can be generated in the target region. In the context of the present disclosure, an expansion device is also understood to mean a device that can reduce the beam diameter. The expansion device can be designed to change the beam diameter of the laser beam without an adjustment of the diameter being possible, e.g., by using a beam telescope. However, it is also provided for the expansion device to be designed to adjust the beam diameter. In this case, the expansion device typically has at least one optical element that is movable, for example displaceable, in the beam path.

In an embodiment, the target region is located in a vacuum chamber and the combination device is located outside the vacuum chamber. To generate the plasma and thus the EUV radiation, it is necessary to arrange the target region, in which the target material is provided in droplet form, in a vacuum environment. As described above, the at least one prepulse laser beam and the main pulse laser beam typically have significantly different wavelengths. The vacuum chamber therefore usually has a separate window for the passage of the prepulse laser beam(s) and the main pulse laser beam, which window allows passage at the prepulse and main pulse laser wavelength, respectively. If the main pulse laser beam has a main pulse wavelength which is of the same magnitude as the prepulse wavelength(s) (e.g., approximately 1 μm), the prepulse laser beam(s) and the main pulse laser beam can pass through a common window.

In an embodiment, the beam-guiding device comprises a focusing optical unit for focusing the first laser beam and the second laser beam into the target region, the focusing optical unit being preferably arranged in the vacuum chamber. As described above, it is typically necessary to focus the at least one prepulse laser beam and the main pulse laser beam in the target region in order to generate the EUV radiation there. The focusing of two or more prepulse laser beams using the focusing optical unit is usually carried out with the same focal length, i.e. the prepulse laser beams are not focused to different degrees by the focusing optical unit. However, the focusing of the main pulse laser beam can be done with a different focal length if necessary.

In an embodiment, the EUV light source comprises a spatially resolving back-reflection detector for detecting radiation reflected back from the target region. When generating the EUV radiation in the target region, part of the focused prepulse and main pulse laser beams is reflected back from the target material in the form of tin droplets. The reflected radiation propagates back through the beam-guiding device and can be analyzed using a spatially resolving detector, e.g., a camera. On the basis of the back-reflected radiation or the position of the prepulse laser beam(s) or the main pulse laser beam on the spatially resolving detector, conclusions can be drawn about the position of the droplet in the target region. Guiding the two laser beams via common optical units makes it possible to use a large numerical aperture to measure the position of each droplet during imaging onto the detector.

In an embodiment, the EUV light source has a spatially resolving detector, arranged downstream of the combination device in the beam path, for detecting the first laser beam and the second laser beam, in particular for detecting the lateral offset between the first laser beam and the second laser beam. In this embodiment, the laser beams in the forward beam path are analyzed downstream of a combination device, as is also described in U.S. Pat. No. 10,932,350 B1. With the aid of the spatially resolving detector, e.g., in the form of a camera, the lateral offset or the relative position(s) of the (at least one) prepulse laser beam and the main pulse laser beam or the two or more prepulse laser beams with respect to one another can be determined. The relative positions of the individual beams correspond—assuming suitable scaling—to the positions of the beams in the target region or at the focus position, since typically only common optical units are used after the combination device (see above). The EUV light source can have an evaluation device for determining the relative focus positions of the laser beams in the target region on the basis of the lateral offset.

In an embodiment, the beam-guiding device has at least one beam splitter device for deflecting the radiation reflected back from the target region onto the back-reflection detector and/or for deflecting a portion of the first laser beam and the second laser beam onto the spatially resolving detector. The deflection of the back-reflected radiation and the portion of the laser beams can be carried out at one and the same beam splitter device, but this is not absolutely necessary. The beam splitter device can be designed to deflect as large a proportion of the back-reflected radiation as possible onto the spatially resolving detector.

In an embodiment, the common beam-guiding device has an optical unit in the form of a telescope arrangement. The telescope arrangement is designed to allow the correct beam diameter to be set in the far field for a given input beam and a given output focal length (which is determined by the distances and, in particular, cannot be shorter). The telescope arrangement is typically arranged in the beam path upstream of the vacuum chamber.

Further features and advantages of embodiments of the present disclosure arise from the following description of exemplary embodiments, with reference to the FIGURES of the drawing. The individual features can be realized in each case individually by themselves or as a plurality in any desired combination in a variant of embodiments of the present disclosure.

Exemplary embodiments are illustrated in the schematic drawing and are explained in the following description.

The FIGURE shows an EUV light source 1, which comprises a first laser source (hereinafter referred to as the first prepulse laser source) 2 in the form of a solid-state laser for emitting a first laser beam (hereinafter referred to as first prepulse laser beam) 3 at a prepulse wavelength λ_{V1} of approximately 1030 nm and a second laser source (hereinafter referred to as second prepulse laser source) 4 in the form of a second solid-state laser for emitting a second laser beam (hereinafter referred to as second prepulse laser beam) 5 at a second prepulse wavelength λ_{V2} of 1064 nm. The EUV light source 1 also comprises a combination device 6, which serves to combine the first prepulse laser beam 3 and the second prepulse laser beam 5, as well as a beam-guiding device 7 for jointly guiding the first prepulse laser beam 3 and the second prepulse laser beam 5 into a target region 8 for generating EUV radiation 9, which is emitted by a target material 10 that is arranged in the target region 8 and is in the form of a tin droplet. The target region 8 with the target material 10 is located in a vacuum chamber 11, in which a provision device provides the target material 10 in the form of tin droplets, which move along a predetermined trajectory through the vacuum chamber 11 and through the target region 8. The focus positions of the first prepulse laser beam 3 and the second prepulse laser beam are in the target region 8 and only slightly deviate from each other in order to hit the target material 10 in the form of the tin droplet. For the following considerations, it is assumed, for the sake of simplicity, that the focus positions of the first prepulse laser beam 3 and the second prepulse laser beam 5 correspond to the position of the target material 10. For the passage of the first prepulse laser beam 3 and the second prepulse laser beam 5, the vacuum chamber 11 has an opening with a window 11a. A main pulse laser beam which is generated by a main pulse laser source in the form of a CO₂ laser with a main pulse wavelength of 10.6 μm is also focused on the target region 8 in the vacuum chamber 11.

As can also be seen in the FIGURE, the first prepulse laser beam 3 from the first prepulse laser source 2 and the second prepulse laser beam 5 from the second prepulse laser source 4 are emitted in a collimated manner and impinge in a collimated manner on the combination device 6, which in the example shown is designed in the form of a prism 6a. A first beam direction (first prepulse beam direction) R_{V1} of the prepulse laser beam 3 and a second beam direction (second prepulse beam direction) R_{V2} of the second prepulse laser beam 5, which impinge in a spatially offset manner on a beam entrance surface 12a of the prism 6a, differ from each other. The combination device 6 in the form of the prism 6a is designed to orient the first prepulse laser beam 3 and the second prepulse laser beam 5 parallel to one another. When exiting the prism 6a at a beam exit surface 12b, 12c, the first prepulse laser beam 3 and the second prepulse laser beam 5 are oriented parallel to one another. The parallel orientation is achieved by a suitable choice of the angles that the beam exit surface 12b, 12c forms with the beam entrance surface 12a as well as of the beam directions R_{V1}, R_{V2} by taking into account the refractive index of the material of the prism 6a.

As can also be seen in the FIGURE, the first prepulse laser beam 3 and the second prepulse laser beam 5 are spatially separated when exiting the combination device 6 and have a lateral offset or distance ΔL from one another. The lateral offset ΔL is maintained during the joint guidance of the first prepulse laser beam 3 and the second prepulse laser beam 5 (in the near field) in the beam-guiding device 7 and is only canceled after the focusing of the first prepulse laser beam 3 and the second prepulse laser beam 5 by means of a focusing optical unit 13, which focuses the first prepulse laser beam 3 and the second prepulse laser beam 5 at a (slightly different) focus position in the target region 8 or onto the target material 8.

As can also be seen in the FIGURE, the EUV light source 1 also has a first beam direction adjusting device (hereinafter referred to as the first prepulse beam direction adjusting device) 14 for adjusting the first prepulse beam direction R_{V1} of the first prepulse laser beam 3. The prepulse beam direction adjusting device 14 comprises three tiltable deflecting mirrors 15a-c, which make it possible to change the first prepulse beam direction R_{V1}. The EUV light source 1 also has a second beam direction adjusting device (hereinafter referred to as second prepulse beam direction adjusting device) 16 for adjusting the second prepulse beam direction R_{V2} of the second prepulse laser beam 5. The second prepulse beam direction adjusting device 16 comprises three tiltable deflecting mirrors 17a-c, which make it possible to change the second prepulse beam direction R_{V2}. By slightly tilting the first prepulse beam direction R_{V1} and the second prepulse beam direction R_{V2} in the near field, the focus positions of the first prepulse laser beam 3, focused in the target region 8 by means of the focusing optical unit 13, and of the second prepulse laser beam 5 can be adjusted with respect to one another. In addition, the focus positions of the first prepulse laser beam 3 and the second prepulse laser beam 5 can be changed jointly by means of a tiltable deflecting mirror 18 arranged downstream of the focusing optical unit 13 in the beam path.

The EUV light source 1 also has a first expansion device (first prepulse expansion device) 19 with a combination of a beam-expanding and a beam-converging optical element in order to change, to enlarge in the example shown, a beam diameter d_{V1} of the first prepulse laser beam 3. In the beam path of the second prepulse laser beam 5, a second expansion device (second prepulse expansion device) 20 is provided for changing a beam diameter d_{V2} of the second prepulse laser beam 5. The second prepulse expansion device 20 also has a beam-expanding and a beam-converging optical element. In the example shown in the FIGURE, the beam diameter d_{V1} of the first prepulse laser beam 3 is substantially doubled by the first prepulse expansion device 19 and the beam diameter d_{V2} of the second prepulse laser beam 5 is substantially halved by the second prepulse expansion device 20. Both the first prepulse expansion device 19 and the second prepulse expansion device 20 are designed not only to change the beam diameter d_{V1}, d_{V2}, but also to adjust it. For this purpose, the distance between the beam-expanding or beam-converging optical elements can be changed.

By changing the beam diameter du, d_{V2}, different focus diameters of the first prepulse laser beam 3 and the second prepulse laser beam 5 can be adjusted in the target region 8, although the joint focusing by means of the focusing optical unit 13 can naturally only be carried out with an identical focal length. When the beam diameter d_{V1} of the first prepulse laser beam 5 is enlarged by a factor of two, as shown in the FIGURE, a beam diameter d_{V1} reduced to half can be generated at the focus position in the target region 8. When the beam diameter d_{V2} of the second prepulse laser beam 5 is reduced to half, as shown in the FIGURE, a beam diameter d_{V2} which is a factor of two larger can be generated at the focus position in the target region 8, provided that the two laser sources 2, 4 each have the same beam quality.

The beam-guiding device 7 also has a telescope arrangement 21 which serves to set the correct beam diameter in the far field for a given input beam and a given output focal length.

The EUV light source 1 also has a spatially resolving back-reflection detector 22, which is designed in the form of a camera. The back-reflection detector 22 serves to detect radiation 23 reflected back from the target region 8, more precisely from the target material 10. The back-reflected radiation 23 passes through the beam-guiding device 7 with a reverse beam direction relative to the first prepulse laser beam 3 and the second prepulse laser beam 5. A beam splitter 24 is used to deflect or decouple the back-reflected radiation 23 in the direction of the back-reflection detector 22. The beam splitter 24 can be designed to be polarization-selective and/or wavelength-selective in order to deflect the back-reflected radiation 23 from the target region 8. The detection of the back-reflected radiation 23 makes it possible to determine the position of the target material 10 in the form of the tin droplet within the target region 8. The back-reflection detector 22 or the optical unit connected upstream of it enables detection with a high numerical aperture.

The beam splitter device 24 also serves to deflect a (power) portion of the first prepulse laser beam 3 and the second prepulse laser beam 5 onto a spatially resolving detector 25 after passing through the combination device 6. In the example shown, the spatially resolving detector 25 is designed in the form of a camera. With the aid of the spatially resolving detector 25, the lateral offset ΔL between the first prepulse laser beam 3 and the second prepulse laser beam 5 can be detected. By means of an evaluation device, the relative position or distance of the focus positions of the first prepulse laser beam 3 and the second prepulse laser beam 5 in the target region 8 can be inferred on the basis of the lateral offset ΔL, since only jointly used optical elements 21, 13, 18 are used in the beam-guiding device 7 following the beam splitter 24.

The beam-guiding device 7 can in principle also have separate optical elements for guiding the first prepulse laser beam 3 and the second prepulse laser beam 5, but this increases the installation space and the number of required components. The use of separate optical elements can, however, be necessary for significantly different prepulse wavelengths λ_{V1}, λ_{V2}. For this reason, the main pulse laser beam which has a main pulse wavelength of approximately 10.6 μm (CO₂ laser beam) is typically guided via a separate optical unit of the beam-guiding device 7 and usually passes through its own window into the vacuum chamber 11. If the main pulse wavelength of the main pulse laser beam does not deviate too greatly from the prepulse wavelength(s), e.g., because the main pulse laser source is a solid-state laser with a main pulse wavelength of, for example, approximately 1 μm, 2 μm or approximately 5 μm, said main pulse laser beam can be combined, instead of the second prepulse laser beam 5 shown in the FIGURE, with the first prepulse laser beam 3 for joint beam guidance in the beam-guiding device 7 in the manner described above in the combination device 6.

Unlike what is shown in the FIGURE, the telescope arrangement 21 and the focusing optical unit 13 can not have lens elements, but rather reflective optical elements or mirrors. Unlike what is shown in the FIGURE, three or more laser beams can also be guided to the combination device 6 via separate beam paths. The three or more laser beams can, for example, be three or more prepulse laser beams, but it is also provided for two or more prepulse laser beams and the main pulse laser beam to be combined in the combination device 6. In the latter case, the combination device 6 typically forms two or more spatially separated prepulse laser beams and one main pulse laser beam, which have a lateral offset from one another.

If the two prepulse wavelengths λ_{V1}, λ_{V2} deviate greatly from each other, an anti-reflection coating can be applied to the transmissive optical units 21, 13 of the beam-guiding device 7, which coating is designed or optimized both to suppress reflections for the first prepulse wavelength λ_{V1} as well as to suppress reflections for the second prepulse wavelength λ_{V2}. For example, quartz glass can be used as material for the transmissive optical units 21, 13. Reflective optical units of the beam-guiding device 7, e.g., the deflecting mirror 18, can be provided with a coating which is optimized for the reflection of the two prepulse wavelengths λ_{V1}, λ_{V2}.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. An extreme ultraviolet (EUV) light source, comprising:
a first laser source for emitting a first laser beam;
a second laser source for emitting a second laser beam;
a combiner configured to combine the first laser beam and the second laser beam; and
a beam-guide configured to jointly guide the first laser beam and the second laser beam into a target region for generating EUV radiation,
wherein the combiner is configured to supply the first laser beam and the second laser beam to the beam-guide for joint beam guidance via common optical units in a spatially separated manner and with a lateral offset.

2. The EUV light source according to claim 1, wherein the first laser source is a prepulse laser source configured to emit a prepulse laser beam and the second laser source is a main pulse laser source configured to emit a main pulse laser beam or an additional prepulse laser source configured to emit an additional prepulse laser beam.

3. The EUV light source according to claim 1, wherein a first wavelength of the first laser beam and a second wavelength of the second laser beam deviate from each other by not more than 70 nm and/or wherein the first wavelength of the first laser beam and the second wavelength of the second laser beam are in a wavelength range between 350 nm and 5 μm.

4. The EUV light source according to claim 3, wherein the beam-guide comprises at least one transmissive optical unit having an anti-reflection coating, which is configured to suppress reflections of the first laser beam at the first wavelength and to suppress reflections of the second laser beam at the second wavelength and/or wherein the transmissive optical unit is formed from quartz glass.

5. The EUV light source according to claim 1, wherein the first laser beam impinges with a first beam direction on the combiner and wherein the second laser beam impinges with a second beam direction different from the first beam direction on the combiner.

6. The EUV light source according to claim 1, wherein the combiner is configured to orient the first laser beam and the second laser beam parallel to one another.

7. The EUV light source according to claim 1, wherein the combiner comprises at least one prism.

8. The EUV light source according to claim 5, further comprising a first beam direction adjuster configured to adjust the first beam direction of the first laser beam and/or a second beam direction adjuster configured to adjust the second beam direction of the second laser beam.

9. The EUV light source according to claim 5, further comprising a first expander configured to adjust a beam diameter of the first laser beam and/or a second expander configured to adjust a beam diameter of the second laser beam.

10. The EUV light source according to claim 1, wherein the target region is located in a vacuum chamber and the combiner is located outside the vacuum chamber.

11. The EUV light source according to claim 1, wherein the beam-guiding device has a focusing optical unit configured to focus the first laser beam and the second laser beam into the target region.

12. The EUV light source according to claim 1, further comprising a spatially resolving back-reflection detector configured to detect radiation reflected back from the target region.

13. The EUV light source according to claim 1, further comprising a spatially resolving detector arranged in a beam path after the combiner and configured to detect the lateral offset between the first laser beam and the second laser beam.

14. The EUV light source according to claim 12, further comprising at least one beam splitter configured to deflect radiation reflected back from the target region onto the back-reflection detector and/or configured to deflect a portion of the first laser beam and the second laser beam onto a spatially resolving detector.

15. The EUV light source according to claim 1, wherein the beam-guide has an optical unit in a form of a telescope arrangement.

16. The EUV light source according to claim 3, wherein the first wavelength of the first laser beam and the second wavelength of the second laser beam deviate from each other by not more than 50 nm and/or wherein the first wavelength of the first laser beam and the second wavelength of the second laser beam are in a range between 500 nm and 2.5 μm.

17. The EUV light source according to claim 10, wherein the beam-guiding device has a focusing optical unit configured to focus the first laser beam and the second laser beam into the target region, the focusing optical unit being arranged in the vacuum chamber.
